(19) United States
(12) Patent Application Publication
(10) Pub. No.: US 2013/0027893 A1
(43) Pub. Date: Jan. 31, 2013

(54) Electromagnetic Interference (EMI) Shields

(71) Applicants: Igor Vinokur, Skokie, IL (US); Gerald R. English, Glen Ellyn, IL (US)

(72) Inventors: Igor Vinokur, Skokie, IL (US); Gerald R. English, Glen Ellyn, IL (US)

(73) Assignee: LAIRD TECHNOLOGIES, INC., Earth City, MO (US)

(21) Appl. No.: 13/532,257

(22) Filed: Jun. 25, 2012

Related U.S. Application Data
(60) Provisional application No. 61/511,438, filed on Jul. 25, 2011.

(51) Int. Cl. H05K 9/00; H05K 13/00; H05K 7/00

(52) U.S. Cl. 361/748; 174/377; 29/592.1

(57) ABSTRACT

Disclosed herein are exemplary embodiments of an EMI shielding apparatus. A frame of the apparatus has a sidewall and an inwardly extending lip defining at least one opening along an upper portion of the frame. A reusable cover is attachable to the frame for at least substantially covering opening(s) of the frame. A first border portion of the cover includes one or more sliding members. A second border portion of the cover includes one or more stops. The sliding member(s) and stop(s) are configured to abut, in generally opposed directions, one or more lip edges generally facing the opening(s) when the cover is attached to the frame. The shielding apparatus is operable for shielding the component(s) on the substrate that are within an interior cooperatively defined by the frame and the cover.

### CROSS-REFERENCE TO RELATED APPLICATION

This application claims the benefit of and priority to U.S. Provisional Application No. 61/511,438 filed Jul. 25, 2011. The entire disclosure of the above application is incorporated herein by reference.

### FIELD

The present disclosure generally relates to shields suitable for shielding components on a printed circuit board from electromagnetic interference (EMI)/radio frequency interference (RFI).

### BACKGROUND

This section provides background information related to the present disclosure which is not necessarily prior art.

Electronic equipment often generates electromagnetic signals in one portion of the electronic equipment that may radiate to and interfere with another portion of the electronic equipment. This electromagnetic interference (EMI) can cause degradation or complete loss of important signals, thereby rendering the electronic equipment inefficient or inoperable. To reduce the adverse effects of EMI, electrically conducting (and sometimes magnetically conducting) material is interposed between the two portions of the electronic circuitry for absorbing and/or reflecting EMI energy. This shielding may take the form of a wall or a complete enclosure and may be placed around the portion of the electronic circuit generating the electromagnetic signal and/or may be placed around the portion of the electronic circuit that is susceptible to the electromagnetic signal. For example, electronic circuits or components of a printed circuit board (PCB) are often enclosed with shields to localize EMI within its source, and to insulate other devices proximal to the EMI source.

As used herein, the term electromagnetic interference (EMI) should be considered to generally include and refer to both electromagnetic interference (EMI) and radio frequency interference (RFI) emissions, and the term “electromagnetic” should be considered to generally include and refer to both electromagnetic and radio frequency from external sources and internal sources. Accordingly, the term shielding (as used herein) generally includes and refers to both EMI shielding and RFI shielding, for example, to prevent (or at least reduce) ingress and egress of EMI and RFI relative to a housing or other enclosure in which electronic equipment is disposed.

### SUMMARY

This section provides a general summary of the disclosure, and is not a comprehensive disclosure of its full scope or all of its features.

Disclosed herein are exemplary embodiments of EMI shielding apparatus including a frame and a cover attachable to the frame. Further aspects of the present disclosure relate to methods of providing EMI shielding.

An exemplary embodiment of an EMI shielding apparatus may be used for providing electromagnetic interference (EMI) shielding for one or more components on a substrate. In this example embodiment, the EMI shielding apparatus generally includes a frame and a cover attachable to the frame. The frame includes a sidewall and an inwardly extending lip defining at least one opening along an upper portion of the frame. The cover is attachable to the frame for at least substantially covering opening(s) of the frame. A first border portion of the cover includes one or more sliding members. A second border portion of the cover includes one or more stops. The sliding member(s) and stop(s) are configured to abut, in generally opposed directions, one or more lip edges generally facing the opening(s) when the cover is attached to the frame. The shielding apparatus is operable for shielding the component(s) on the substrate that are within an interior cooperatively defined by the frame and the cover.

In another exemplary embodiment, the disclosure is directed to a reusable cover for a shielding apparatus for use in providing electromagnetic interference (EMI) shielding for one or more components on a substrate. The apparatus includes a frame having a sidewall and an inwardly extending lip defining at least one opening along an upper portion of the frame. The cover has a first border portion with one or more sliding members. A second border portion of the cover has one or more stops. The sliding member(s) and stop(s) are configured to abut, in generally opposed directions, one or more lip edges generally facing the opening(s) when the cover is attached to the frame. The cover is attachable to the frame to at least substantially cover the frame's opening(s) and to shield the component(s) on the substrate that are within an interior cooperatively defined by the frame and the cover.

In yet another embodiment, the disclosure is directed to a method relating to board-level electromagnetic interference (EMI) shielding of one or more electrical components of a board. One or more sliding members of a first border portion of a cover are inserted at least partly beneath an inwardly extending lip that defines one or more openings along an upper portion of a frame having a sidewall. The cover is moved relative to the frame to move one or more stops of a second border portion of the cover toward contact with the frame's lip and to at least partially release the sliding member(s) of the first border portion of the cover from beneath the lip to abut an edge of the lip. The cover at least substantially covers the frame's opening(s) to shield, in cooperation with the frame, the components from electromagnetic interference.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a top perspective view of an EMI shielding apparatus according to an exemplary embodiment of the present disclosure, a cover of the apparatus being shown as attached to a frame of the apparatus;

FIG. 2A is a bottom perspective view of an EMI shielding apparatus according to an exemplary embodiment of the present disclosure, a cover of the apparatus being shown as attached to a frame of the apparatus;

FIGS. 2B and 2C are cutaway interior perspective views of an EMI shielding apparatus according to an exemplary embodiment of the present disclosure, a cover of the apparatus being shown as attached to a frame of the apparatus;

FIG. 3 is a top perspective view of a frame of an EMI shielding apparatus according to an exemplary embodiment of the present disclosure;

FIG. 4 is a top perspective view of a cover of an EMI shielding apparatus according to an exemplary embodiment of the present disclosure;

FIG. 5 is a top perspective view of a cover of an EMI shielding apparatus according to an exemplary embodiment of the present disclosure;

FIG. 6A is a sectional view of an EMI shielding apparatus according to an exemplary embodiment of the present disclosure;

FIGS. 6B and 6C are enlarged partial sectional views of the apparatus shown in FIG. 6A;

FIGS. 7A and 7B are cutaway sectional views of the apparatus shown in FIGS. 6A-6C;

FIGS. 8A and 8B are cutaway sectional views of the apparatus shown in FIGS. 6A-6C; and

FIG. 9 is a top perspective view of a flat profile pattern for a cover of an EMI shielding apparatus according to an exemplary embodiment of the present disclosure.

### DETAILED DESCRIPTION

Example embodiments will now be described more fully with reference to the accompanying drawings.

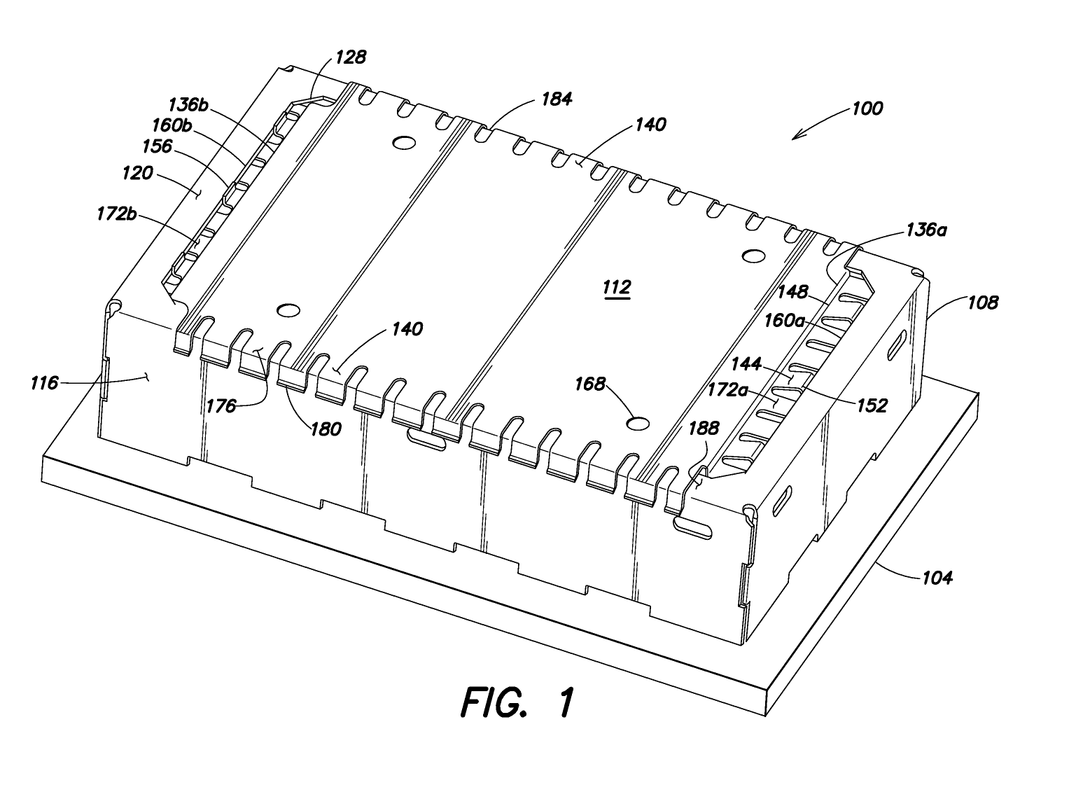

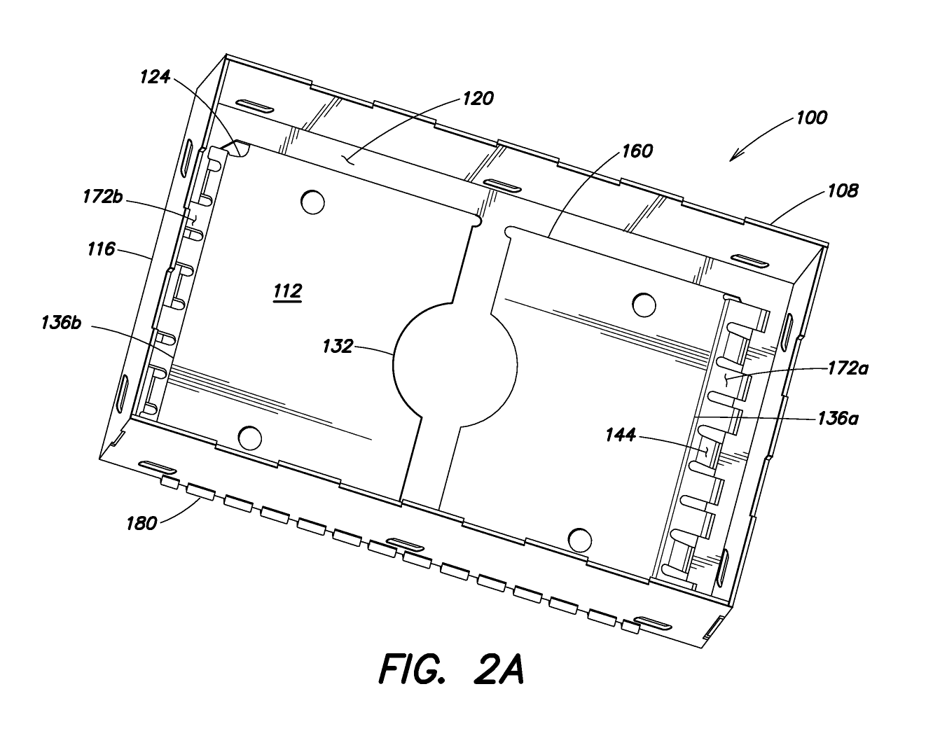

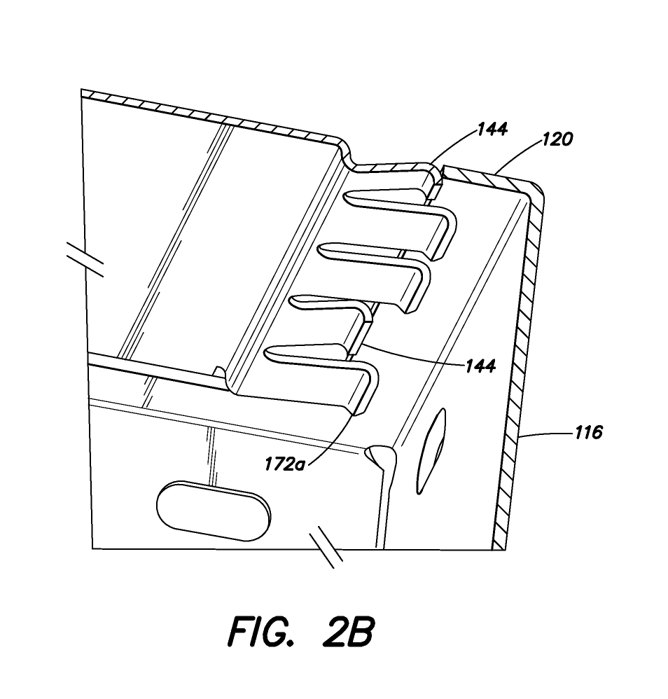

Referring now to the drawings, FIGS. 1 and 2A-2C illustrate an exemplary embodiment of a shielding apparatus or shield 100 embodying one or more aspects of the present disclosure. The shielding apparatus 100 may be installed to a printed circuit board 104 (a PCB, and broadly a substrate) and is suitable for use in providing electromagnetic interference (EMI) shielding to one or more components mounted on the PCB 104. For example, the shielding apparatus 100 may shield component(s) on the substrate 104 that are within an interior cooperatively defined by a frame 108 and a cover 112 of the shield 100. The frame 108 may be attached to the substrate 104 in various ways, for example, by soldering and/or by attachment members extending into the substrate 104.

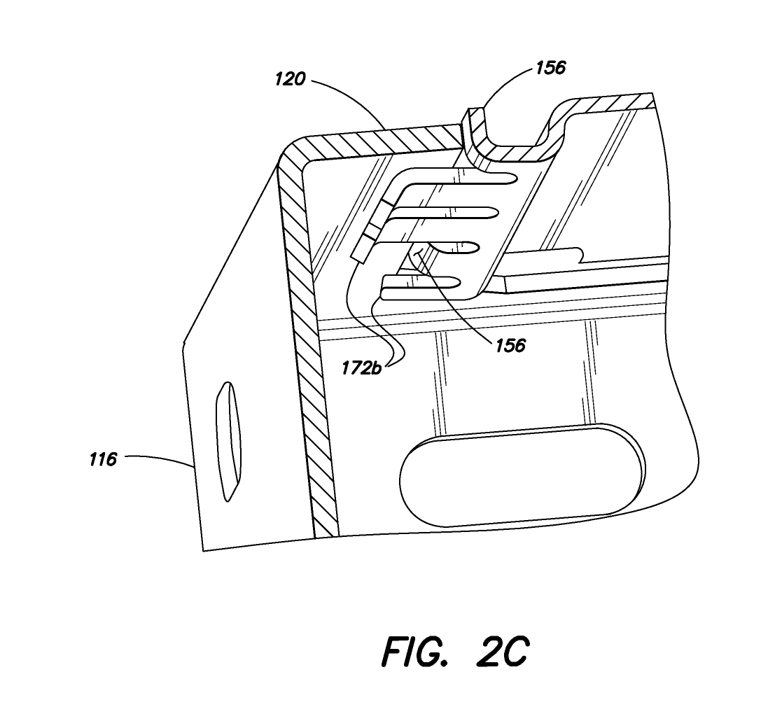

The frame 108 has one or more sidewalls 116. In various configurations the frame may have discrete sidewalls and/or a continuous sidewall. The frame 108 (and/or other frames and covers disclosed herein) may be formed from a single piece of electrically conductive material (e.g., a single blank of material, etc.). Additionally or alternatively, and as shown, for example, in FIG. 3, a frame 200 may be formed so that a side wall 208 of the frame has an integral, monolithic construction.

Referring again to FIGS. 1 and 2A-2C, a wide range of electrically conductive materials may be used to form the frame 108 and/or cover 112, such as those disclosed herein. The sidewall(s) 116 have an inwardly extending lip 120 defining at least one opening 124 along an upper portion 128 of the frame 108. As shown, for example, in FIG. 2A, a flat cross bracing or portion 132 may be provided for making electrical contact with the cover 112 to provide EMI shielding. Additionally or alternatively, the flat portion 132 may be used for vacuum or mechanical pick and place operations. The flat portion 132 extends across the frame to define two openings 124. In some other embodiments, more or less than two flat portions and/or more or less than two openings may be provided. Additionally or alternatively, in some embodiments there may be provided one or more internal walls (not shown) in a frame that may cooperate with the cover to provide various EMI shielding compartments.

The cover 112 is releasably or removably attachable to the frame 108 to at least substantially cover the opening(s) 124. The cover 112 may be removed, for example, to allow for testing, repair, and/or replacement of the electronic or electrical components on the PCB 104, after which the cover 112 may be reattached to the frame 108. The cover 112 includes two generally opposed border portions 136a and 136b and two side border portions 140. The border portion 136a includes one or more sliding members 144. Each sliding member 144 includes a curved or bent portion 148 and a stopper or stop 152. The border portion 136b includes one or more stops or stoppers 156. When the cover 112 is attached to the frame 108, e.g., as shown in FIGS. 1 and 2A-2C, the sliding member(s) 144 and stop(s) 156 abut, in generally opposed directions, one or more lip edges 160 generally facing the opening(s) 124. For example, the stopper(s) 152 of the sliding member(s) 144 abut an inner edge 160a of the lip 120, and the stop(s) 156 abut an inner edge 160b of the lip 120. (The lip edges 160a and 160b could, but do not necessarily, form a continuous edge 160.) The cover 112 may also include one or more apertures or holes 168.

One or both of the border portions 136a and 136b of the cover 112 also may respectively include one or more tabs 172a and/or 172b cooperatively arranged with the sliding member(s) 144 and with the stop(s) 156 to removably retain the border portions 136a and 136b of the cover in engagement with the lip 120 of the frame 108. The tabs 172a and/or 172b are configured to fit at least partly beneath the lip 120 when the cover 112 is attached to the frame 108. In the example configuration shown in FIGS. 1 and 2A-2C, two tabs 172a are provided between consecutive sliding members 144, which may be generally aligned with the tabs 172a. Similarly, two tabs 172b are provided between consecutive stops 156, which may be generally aligned with the tabs 172b. It also is contemplated that numbers, sizes, and arrangements of sliding members, stops and/or tabs could be asymmetrical in some configurations, for example, to accommodate an asymmetrical frame. Tabs may vary, e.g., in width, shape, and/or length. Further, some or all tabs could be omitted from a cover in some configurations.

As shown, e.g., in FIGS. 1 and 2A, the side border portions 140 include tabs 176 terminating in clips 180 for attaching the cover 112 along outer edges 184 of the frame 108. In various configurations, such clips might not be provided. For example, in some configurations some or all of the tabs 176 may terminate on a top surface 188 of the frame lip 120. Additionally or alternatively, at least parts of the side border portions 140 may not be provided, and at least parts of the cover may terminate at or before reaching an inner edge 160 of the lip 120. Further, in various configurations at least some of the sliding member(s) and/or stop(s) of the cover may be formed at least partly from resilient or compliant material and appropriately positioned to generally outwardly bias the cover border portions 136a and 136b against the lip 120 of the frame 108 when the cover 112 is attached to the frame 108. Such configurations may provide a cover having the same or a smaller “footprint” relative to the PCB than a frame to which the cover may be attached.

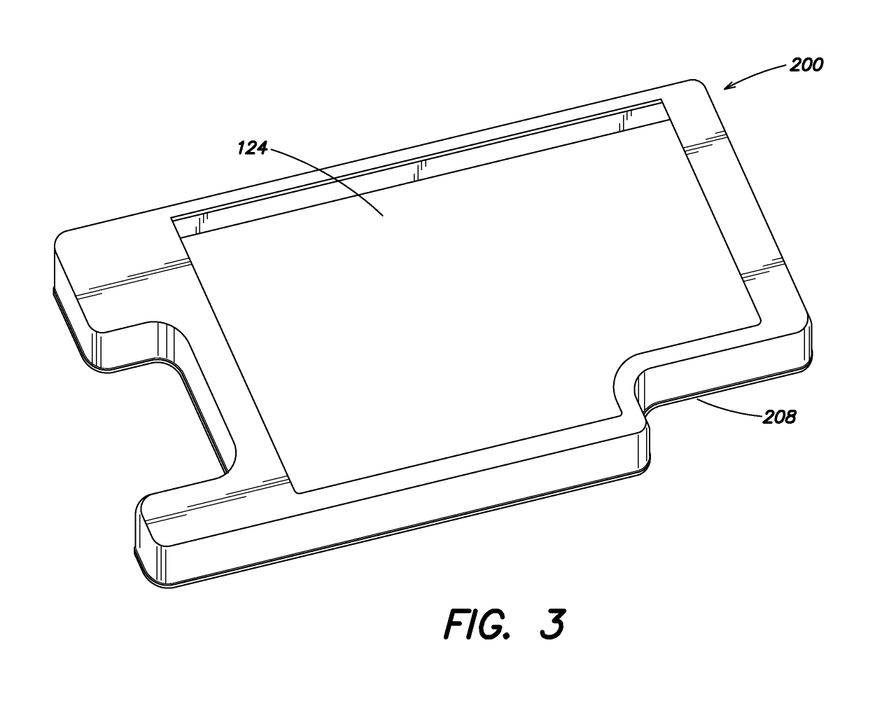

Another configuration of a cover for an EMI shielding apparatus is indicated generally in FIG. 4 by reference number 300. The cover 300 may, for example, be used in or form part of a shielding apparatus having an overall height greater than about 1.2 millimeters when the cover 300 is attached to a frame, e.g., the frame 200 shown in FIG. 3. The cover 300 illustrated in FIG. 4 has a border portion 304 that includes three stops 308. The border portion 304 is longer than a generally opposed border portion 312 that includes three sliding members 316. The cover 300 also includes four side border portions 320, 324, 328, and 332 that collectively include a plurality of tabs 336 terminating in clips 340.

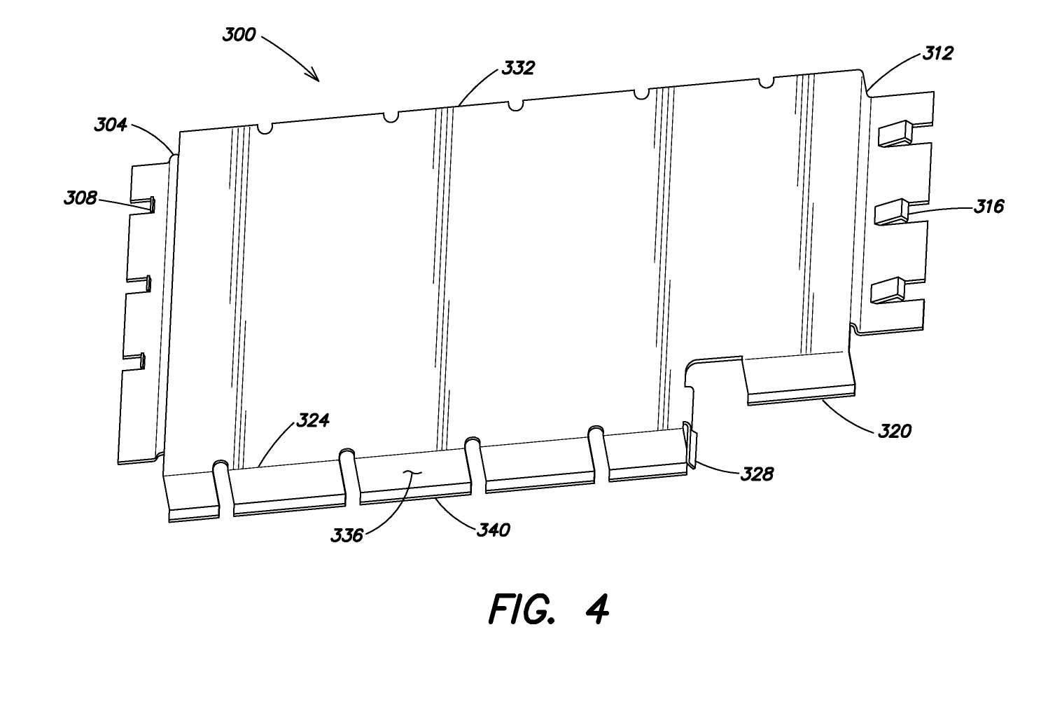

Still another configuration of a cover for an EMI shielding apparatus is indicated generally in FIG. 5 by reference number 400. The cover 400 may, for example, be used in or form part of a shielding apparatus having a height less than about 1.2 millimeters when the cover 400 is attached to a frame of the apparatus. The cover 400 has a border portion 404 that includes three stops 408. The border portion 404 is longer than a generally opposed border portion 412 that includes three sliding members 416. The cover 400 also includes side border portions 420, 424 and 428 that collectively include a plurality of tabs 432. The tabs 432 are configured to lie on an upper surface of a lip of a frame (or under a lower surface in other embodiments) to which the cover may be attached. It should be noted generally that embodiments are possible in which a reusable cover is removably attachable to a frame to provide a shielding assembly having a height less than one millimeter, e.g., about 0.7 millimeter.

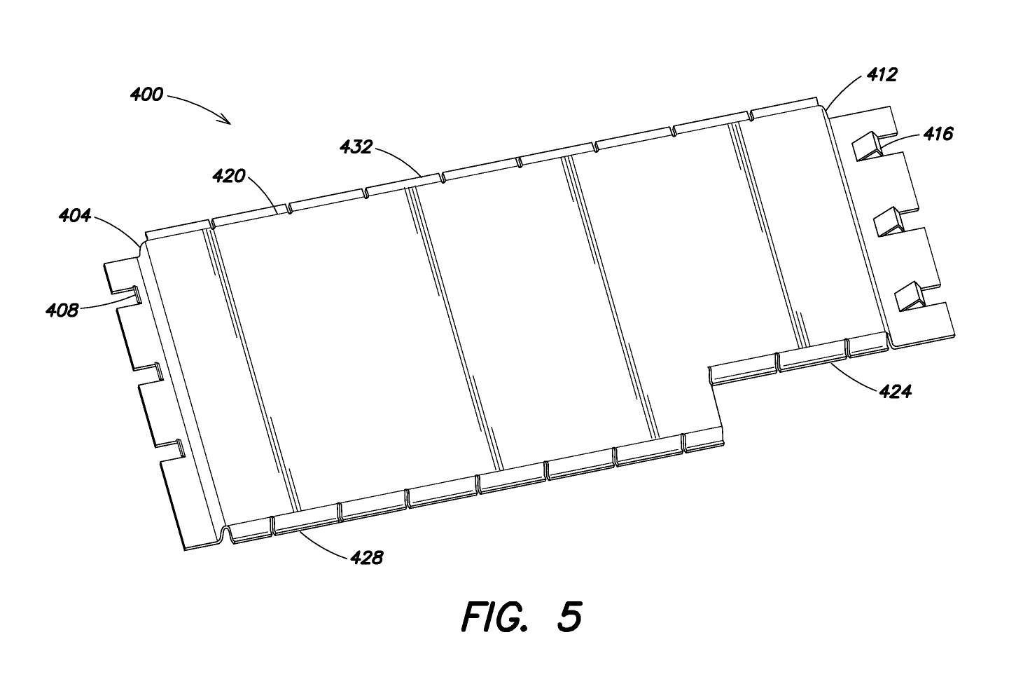

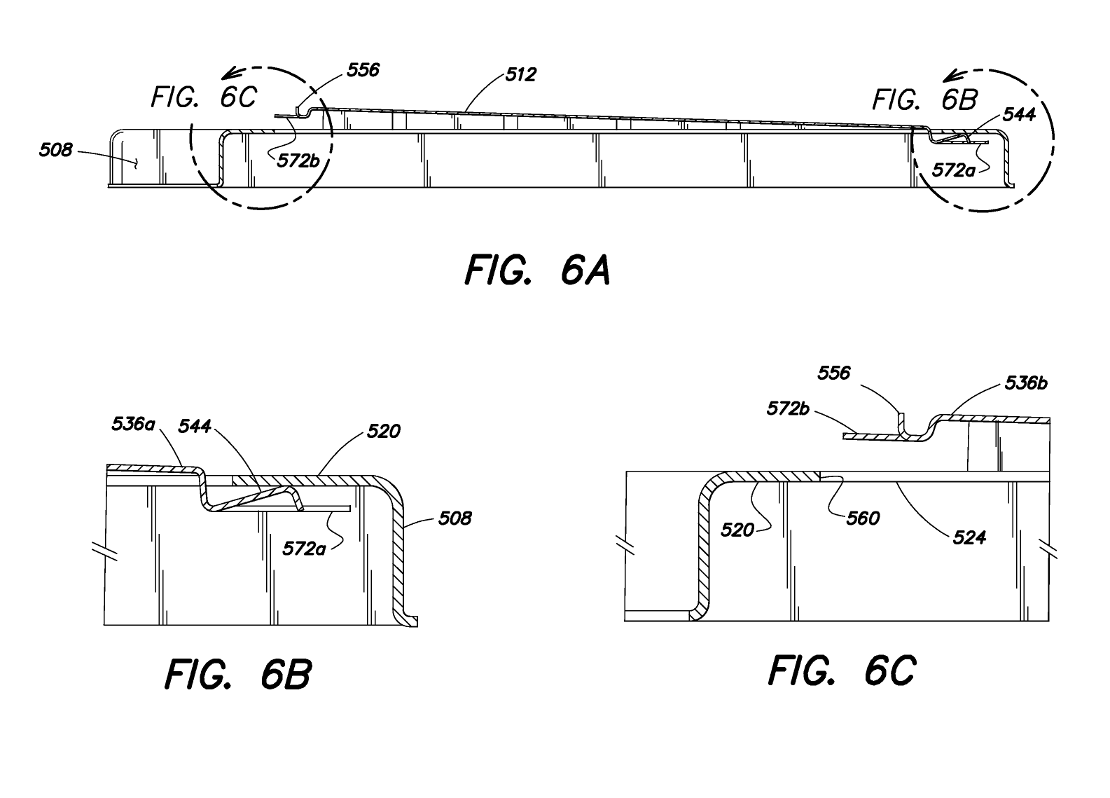

By way of example only and with reference to FIG. 6A through FIG. 8B, a description will now be provided of an exemplary method by which a cover 512 may be removably attached to a frame 508. A border portion 536a of the cover 512, including sliding member(s) 544 and tab(s) 572a, is at least partly inserted under a lip 520 of the frame 508, e.g., as shown in FIGS. 6A and 6B. The lip 520 has an inner edge 560 that is continuous around an opening 524 defined by the lip 520. Inserting the border portion 536a under the lip 520 may cause the generally opposed cover border portion 536b, including the tab(s) 572b and stop(s) 556, to be moved away from the lip 520. Thus, clearance may be provided to the tab(s) of the border portion 536b relative to the inner edge 560 of the lip 520, e.g., as shown in FIGS. 6A and 6C.

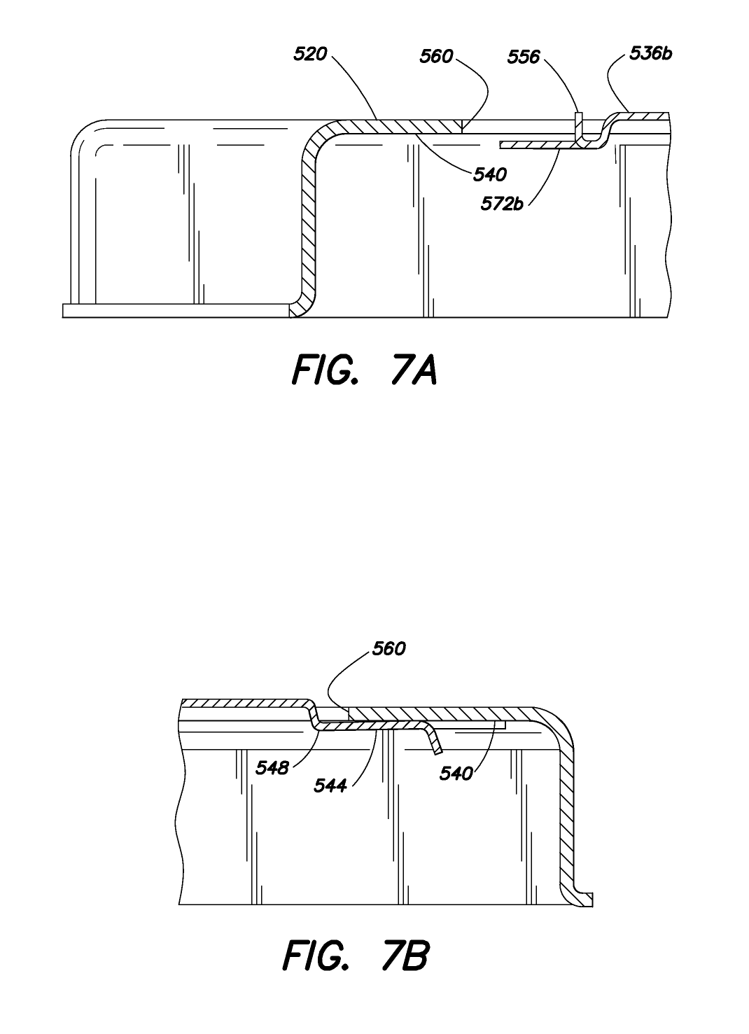

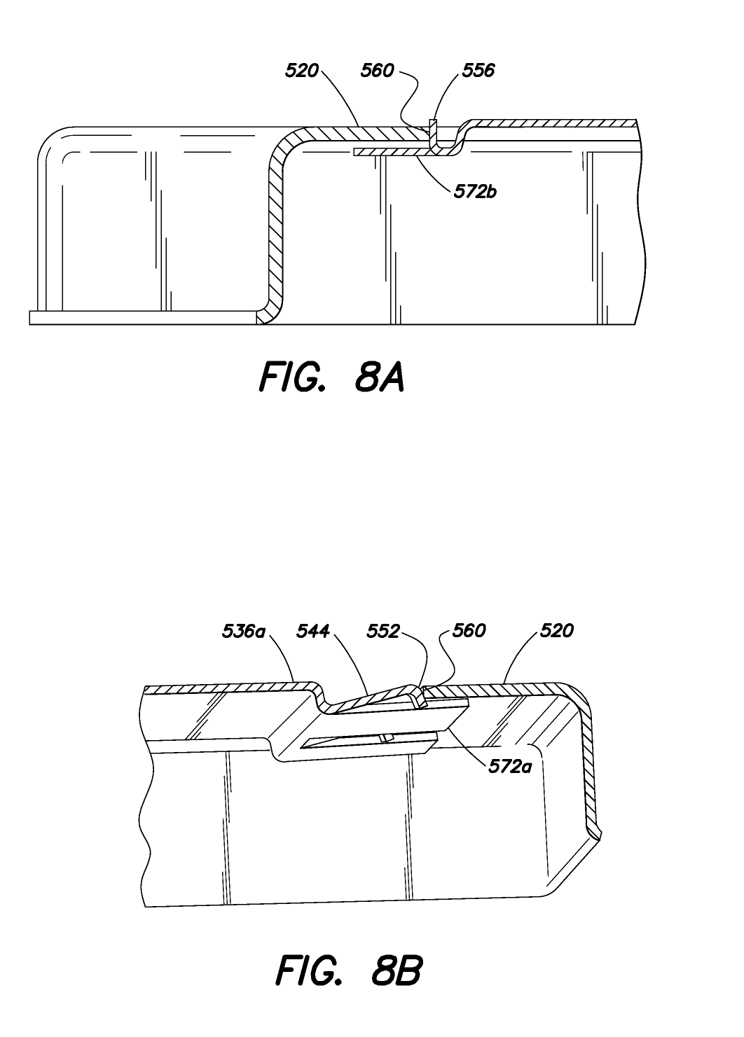

After the sliding member(s) 544 and tab(s) 572a are inserted beneath the lip 520, the cover border portion 536b may be lowered (as shown by a comparison of FIG. 6C with FIG. 7A). The stop(s) 556 and tab(s) 572b may be moved toward the lip 520, e.g., as shown by comparing the relative positioning of the stop(s) 556 and lip 520 in FIG. 7A with that shown in FIG. 8A. When the border portion 536b is lowered, the sliding member(s) 544 of the border portion 536a may be elevated toward and against an undersurface 540 of the lip 520. For example, a normally curved or bent portion 548 of a sliding member 544 may be biased into a more open configuration, e.g., as shown in FIG. 7B. As the stop(s) 556 are moved toward contact with the inner edge 560 of the lip 520 and the tab(s) 572b are moved beneath the lip, the sliding member(s) 544 of the border portion 536a become at least partially released from beneath the lip 520 while at least part of the tab(s) 572a remain beneath the lip 520. Thus, the stop(s) 556 abut the lip inner edge 560, e.g., as shown in FIG. 8A, and the stopper(s) 552 of the sliding member(s) 544 abut the lip inner edge 160, e.g., as shown in FIG. 8B.

To remove the cover 512 from the frame 508, the stopper(s) 552 of the sliding member(s) 544 are pressed beneath the lip edge 560. The cover 512 then is moved in the direction of the border portion 536a to disengage the stop(s) 556 and tab(s) 572b from the lip edge 560. The cover 512 may then be completely removed from the opening 524.

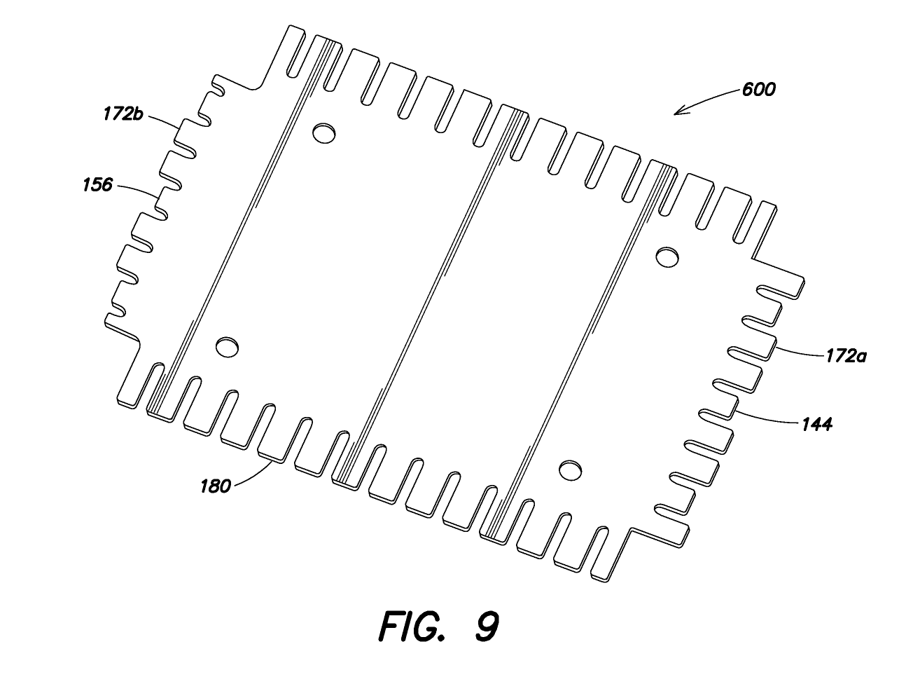

In an exemplary embodiment as shown in FIG. 9, a flat profile pattern 600 for the cover 112 (and/or other covers disclosed herein) may be stamped into a piece of material. The flat profile pattern may include the sliding members 144, stops 156, and tabs 172a and 172b. The flat profile pattern 600 may also include clips 180. The sliding members 144, stops 156, and (if any) clips 180 may then be formed, bent, drawn, shaped, folded, etc. into the configuration shown in FIGS. 1 and 2A-2C (e.g., bent portions of sliding members 144 and stops 156, etc.) Even though the cover 112 may be formed (e.g., by stamping and bending/folding/drawing, etc.) from the same piece of material substantially simultaneously in this example, such is not required for all embodiments. For example, other embodiments may include one or more discrete components separately attached to the cover 112, for example, by welding, adhesives, among other suitable methods. Alternative configurations (e.g., shapes, sizes, etc.), materials, and manufacturing methods may be used for making the cover 112. In addition, the cover 112 is illustrated as a single-piece cover that is operable with a single-piece frame for shielding one or more components on the PCB 104 that are within an interior cooperatively defined by a shield's sidewalls 116 and cover 112. Some other embodiments may include multi-piece frames and/or multi-piece covers.

In the example embodiment shown in FIG. 1, the shield 100 includes four sidewalls 116 providing a generally rectangular shape. In other exemplary embodiments, shields may include more than or fewer than four sidewalls and/or in a configuration different from that shown in the figures herein. For example, the shield may have square configurations, triangular configurations, hexagonal configurations, other polygonal-shaped configurations, circular configurations, non-rectangular configurations, etc. Shields accordingly may have differently configured openings (e.g., different shapes, sizes, locations, etc.) and covers may have differently configured shapes to substantially cover such openings.

The apertures or holes 168 of the cover (FIG. 1) may facilitate solder reflow heating interiorly of the shield 100, may enable cooling of the electrical components within the shield 100, and/or may permit visual inspection of members of the electrical components beneath the shield 100. In some exemplary embodiments, shields may include holes that are sufficiently small to inhibit passage of interfering EMI. The particular number, size, shape, orientation, etc. of the holes may vary depending, for example, on the particular application (e.g., sensitivity of the electronics where more sensitive circuitry may necessitate the use of smaller diameter holes, etc.). For example, some exemplary shields may include covers without any such holes.

As previously discussed with reference to FIG. 2A, a frame of a shield may include a generally central pick-up surface configured for use in handling the shield with pick-and-place equipment (e.g., vacuum pick-and-place equipment, etc.). The pick-up surface may be configured for use as a pick-up area that may be gripped or to which suction may be applied by the pick-and-place equipment for handling during, for example, fabrication of the shield 100 and/or original installation of the shield 100 to the PCB 104. The pick-up surface may allow for balanced manipulation of the shield 100 during handling of the shield 100. In other exemplary embodiments, a shield may include tabs at corners and/or along side edges for use as pick-up surfaces in addition to or instead of centrally located pick-up surfaces.

In various configurations of the foregoing shield, a cover is attached to a frame inward of the sidewalls by engagement with the inwardly extending lip of the frame. This allows for a reduced shield footprint size relative to area and/or volume requirements under the shield. Given the ever-reducing sizes and miniaturization of electronic devices, it can be highly beneficial to reduce footprint size by as much as possible. Because the cover is releasably and removably attached to the frame by means of the inwardly extending lip, attachment of the cover in many configurations does not add any length, width, or height to the frame or shield. Thus, a two-piece shield configured in accordance with embodiments of the present disclosure advantageously provides a removable and reusable cover without increasing the overall size of the shield, as compared, e.g., with a single-piece shielding can. Furthermore, it is possible to use a frame that has virtually no holes or slots. For example, exemplary embodiments of a shield include a cover releasably and removably attachable to a frame of the shield without using, requiring, or engaging dimples and holes in the sidewalls of the cover and shield. In such embodiments, the connection of the shield to the cover is accomplished along the top of the frame, and is not accomplished by or along downwardly depending sidewalls of the cover and frame. Shields configured in accordance with the present disclosure are in contrast to existing two-piece shields in which extra space is required because of attachments features such as dimples or protrusions on the frame or cover sidewalls.

As used in the present disclosure and claims, the term “generally opposed” may refer to elements or directions that may or may not be directly opposed to each other, i.e., 180 degrees apart. “Generally opposed” directions can include directions having fewer or more than 180 degrees between them. For example, in some embodiments a cover may have three or more border portions that may cooperatively allow a cover to be attached to a frame as disclosed herein. The stop(s) and/or sliding member(s) of such a cover might abut lip edge(s) of the frame in “generally opposed” directions. It can be appreciated that how two or more border portions might be configured to allow a cover to be removably attached in a frame could be affected by numerous factors, e.g., sizes and/or shapes of frame openings, sizes, lengths and/or curvature of sliding members and/or of stops, thickness and/or resiliency of materials used in the cover and/or frame lip, angles at which sliding members and/or stops abut the lip and/or bias the cover, etc.

A non-exhaustive list will now be provided of exemplary materials from which an embodiment of an EMI shielding apparatus may be made. Exemplary materials include cold rolled steel, nickel-silver alloys, copper-nickel alloys, stainless steel, tin-plated cold rolled steel, tin-plated copper alloys, carbon steel, brass, copper, aluminum, copper-beryllium alloys, phosphor bronze, steel, alloys thereof, or any other suitable electrically-conductive and/or magnetic materials. In addition, an EMI shielding apparatus may be formed from a plastic material coated with electrically-conductive material. In one exemplary embodiment, an EMI shielding apparatus is from a sheet of nickel-silver alloy having a thickness of about 0.13 millimeters. The materials provided herein are for purposes of illustration only, as an EMI shielding apparatus may be configured from different materials depending, for example, on the particular application, such as the components to be shielded, space considerations within the overall device, EMI shielding and heat dissipation needs, and other factors.

Numerical dimensions and values are provided herein for illustrative purposes only. The particular dimensions and values provided are not intended to limit the scope of the present disclosure.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter. The disclosure of a first value and a second value for a given parameter can be interpreted as disclosing that any value between the first and second values could also be employed for the given parameter. Similarly, it is envisioned that disclosure of two or more ranges of values for a parameter (whether such ranges are nested, overlapping or distinct) subsume all possible combination of ranges for the value that might be claimed using endpoints of the disclosed ranges.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. A shielding apparatus for use in providing electromagnetic interference (EMI) shielding for one or more components on a substrate, the shielding apparatus comprising:
a frame having at least one sidewall and an inwardly extending lip defining at least one opening along an upper portion of the frame; and
a cover attachable to the frame for at least substantially covering the at least one opening of the frame, the cover having first and second border portions, the first border portion having one or more sliding members and the second border portion having one or more stops;
the one or more sliding members and the one or more stops configured to abut, in generally opposed directions, one or more lip edges generally facing the at least one opening when the cover is attached to the frame;
whereby the shielding apparatus is operable for shielding the one or more components on the substrate that are within an interior cooperatively defined by the frame and the cover.

2. The shielding apparatus of claim 1, wherein the first and second border portions of the cover have one or more tabs cooperatively arranged with the one or more sliding members and with the one or more stops to removably retain the first and second border portions of the cover in engagement with the lip.

3. The shielding apparatus of claim 1, wherein the first and second border portions of the cover have one or more tabs configured to fit at least partly beneath the lip of the frame when the cover is attached to the frame.

4. The shielding apparatus of claim 1, wherein:
the first border portion of the cover is at least partly insertable under the lip of the frame to allow movement of the second border portion of the cover toward engagement with the lip; and
the one or more sliding members are configured to be at least partly released from under the lip by the movement to bias the first and second border portions of the cover against the lip in cooperation with the one or more stops.

5. The shielding apparatus of claim 1, wherein the one or more sliding members are at least partly extendible beneath the lip to attach the cover to or remove the cover from the frame.

6. The shielding apparatus of claim 1, wherein the one or more sliding members and the one or more stops press against the lip when the cover is attached to the frame.

7. The shielding apparatus of claim 1, wherein one of the one or more sliding members has a stopper configured to abut the lip of the frame when the cover is attached to the frame, the stopper further configured to be pushed beneath the lip to allow removal of the cover from the frame.

8. The shielding apparatus of claim 7, wherein the stopper is further configured to bias the cover against the lip when the cover is attached to the frame.

9. The shielding apparatus of claim 1, wherein the sidewall of the frame has no holes or slots.

10. The shielding apparatus of claim 1, wherein the shielding apparatus is configured to have a total height of less than one millimeter when the cover is attached to the frame.

11. An electrical device including a printed circuit board with one or more components thereon, and the shielding apparatus of claim 1.

12. A reusable cover for a shielding apparatus for use in providing electromagnetic interference (EMI) shielding for one or more components on a substrate, the apparatus including a frame having a sidewall and an inwardly extending lip defining at least one opening along an upper portion of the frame, the cover comprising:
a first border portion having one or more sliding members;
a second border portion having one or more stops;
the one or more sliding members and the one or more stops configured to abut, in generally opposed directions, one or more lip edges generally facing the at least one opening when the cover is attached to the frame;
whereby the cover is attachable to the frame to at least substantially cover the at least one opening and to shield the one or more components on the substrate that are within an interior cooperatively defined by the frame and the cover.

13. The cover of claim 12, wherein:
the first and second border portions each comprise one or more tabs;
the one or more sliding members are configured to be biased against an underside of the lip when the tabs of the first border portion of the cover are inserted at least partly beneath the lip; and
the one or more sliding members are further configured to be at least partly released to bias the cover against the lip in cooperation with the stops when the tabs of the second border portion of the cover are inserted at least partly beneath the lip.

14. The cover of claim 12, wherein the cover is reusable as to a different frame having a different sidewall height.

15. The cover of claim 12, wherein one of the one or more sliding members has a stopper configured to bias the cover against the lip of the frame when the cover is attached to the frame, the stopper further configured to be pushed beneath the lip to allow removal of the cover from the frame.

16. A method relating to board-level electromagnetic interference (EMI) shielding of one or more electrical components of a board, the method comprising:
inserting one or more sliding members of a first border portion of a cover at least partly beneath an inwardly extending lip that defines one or more openings along an upper portion of a frame having a sidewall; and
moving the cover to move one or more stops of a second border portion of the cover toward contact with the lip and to at least partially release the one or more sliding members of the first border portion of the cover from beneath the lip to abut an edge of the lip;
whereby the cover at least substantially covers the one or more openings to shield, in cooperation with the frame, the one or more electrical components from electromagnetic interference.

17. The method of claim 16, further comprising:
inserting one or more tabs of the second border portion of the cover at least partly beneath the lip of the frame to move the one or more stops toward the lip and to release the one or more sliding members of the first border portion;
the inserting of the one or more tabs of the second border portion performed while leaving one or more tabs of the first border portion at least partly beneath the lip.

18. The method of claim 16, further comprising moving the attached cover in the direction of the first border portion while lifting the second border portion of the cover, the moving and lifting performed to remove the cover from the frame.

19. The method of claim 16, further comprising:
removing the cover from the frame; and
reattaching the cover to the frame.

20. The method of claim 16, wherein the shielding apparatus has a height of less than one millimeter when the cover is attached to the frame.
